(19) United States
(12) Patent Application Publication
(10) Pub. No.: US 2008/0215952 A1
(43) Pub. Date: Sep. 4, 2008

(54) HYBRID FLASH MEMORY DEVICE, MEMORY SYSTEM, AND METHOD CONTROLLING ERRORS

(75) Inventor: Il-Man BAE, Suwon-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 11/962,445

(22) Filed: Dec. 21, 2007

(30) Foreign Application Priority Data
Jan. 4, 2007 (KR) 10-2007-0001045

(51) Int. Cl. G11C 29/00; H03M 13/15; G06F 11/07

(52) U.S. Cl. 714/756; 714/773; 714/782; 714/767; 714/E11.021

(57) ABSTRACT

Provided is a hybrid flash memory device, a memory system, and a method of controlling errors. The hybrid flash memory device includes a data storage block with first and second data storage regions of flash memory cells, and error control block implementing first and second error control schemes, such that a data access operation directed to data stored in the first data storage region selects the first error control scheme, and a data access operation directed to data stored in the second data storage region selects the second error control scheme.

### CROSS-REFERENCE TO RELATED APPLICATIONS

This U.S. non-provisional patent application claims priority under 35 U.S.C. § 119 to Korean Patent Application No. 10-2007-0001045 filed on Jan. 4, 2007, the subject matter of which is hereby incorporated by reference.

### BACKGROUND OF THE INVENTION

1. Field of the Invention

The present invention relates to a semiconductor memory device. More particularly, the invention relates to a hybrid flash memory device.

2. Description of the Related Art

Flash memory is one type of non-volatile memory capable of retaining stored data when applied power is interrupted. While data access speeds for flash memory are slower than those associated with volatile memory devices such as Dynamic Random Access Memory (DRAM), they are markedly faster than data access speeds for hard disk drives (HDDS). When generally used as a replacement for HHDs, flash memory affords improved power consumption properties and improved durability relative to mechanical impacts. Thus, flash memory is used extensively in applications and various electronic devices running from battery power.

Flash memory is generally capable of having data electrically written to it (i.e., programmed) and erased. Unlike EEPROMs, flash memory may be programmed and erased on a block by block basis. Moreover, flash memory is generally very high capacity and allows data to be stored at lower cost per bit than EEPROMs. Typical applications benefiting from the use of flash memory include digital music players, digital cameras, mobile phones, etc. Flash memory enabled USB drivers (or flash memory cards) are widely used for storing data and for transferring data between computers.

Flash memory typically stores data in an array of memory cells having floating gate transistors. Newer flash memory is capable of storing multiple data bits per memory cell. For convenience of description, a memory cell in a flash memory device storing 1 bit of data is called a single-bit cell (SBC). A memory cell in a flash memory device storing multiple bits of data is called a multi-bit cell (MBC).

In a SBC flash memory device, data stored in each memory cell may be identified using an appropriate read voltage intermediate to the threshold voltage distribution for data having a defined value of “1” and the threshold voltage distribution for data having a defined value of “0”. For example, when the read voltage is applied to a control gate of the memory cell, it is possible to determine whether a data value of 0 or 1 is stored by detecting a corresponding current flow passing through the memory cell.

Voltage margins between the read voltage and the respective threshold voltage distributions in a SBC flash memory device are generally greater than those in a MBC flash memory device. Read errors nonetheless occur in either device type. Therefore, an error detection and/or correction (ECC) scheme may be used to detect and/or correct bit errors. One ECC scheme is disclosed, for example, in U.S. Pat. No. 6,651,212, the subject matter of which is hereby incorporated by reference.

As the number of data bits stored per memory cell increases in a MBC flash memory device, more threshold voltage distributions are used and must be accounted for. As well known in the field of flash memory, there have been certain difficulties associated with leveling up the threshold voltage distributions in a flash memory using MBCs. That is, the threshold voltage of a memory cell ranges within a predetermined voltage. Accordingly, the threshold voltage distributions being used for a particular MBC should to be evenly distributed across this voltage range regardless of the number of data bits being stored by the MBC. However, for a certain number of stored data bits per memory cell, this design goal may cause adjacent threshold voltage distributions to overlap. This outcome becomes a serious impediment to further increases in the number of data bits that a MBC may store. Furthermore, this outcome poses a serious problem to various design factors such as charge loss, read/program operation time periods, device heating, charge coupling during program/read of adjacent memory cells, cell defects, etc.

In sum, as the design and fabrication difficulties associated with MBC flash memory devices expand, the benefits of a competent ECC functionality become increasingly compelling.

### SUMMARY OF THE INVENTION

Certain embodiments of the invention provide an error control scheme appropriate for a hybrid flash memory device, and/or an error control scheme appropriate for a memory system within a hybrid flash memory device.

In one embodiment, the invention provides a hybrid flash memory device having an Error Control and Correction (ECC) capability, and comprising; a control block responsive to an externally provided command, a data storage block comprising a first data storage region including first flash memory cells and a second data storage region including second flash memory cells, wherein the first and second flash memory cells store a different number of data bits per memory cell, and an error control block comprising a first ECC block implementing a first error control scheme and a second ECC block implementing a second error control scheme, wherein if the command indicates a data access operation directed to data stored in the first data storage region, the control block selects operation of the first ECC block such that the error control block operates in accordance with the first error control scheme, and wherein if the command indicates a data access operation directed to data stored in the second data storage region, the control block selects operation of the second ECC block such that the error control block operates in accordance with the second error control scheme.

In another embodiment, the invention provides a memory system comprising; a memory controller responsive to a command received from a host device to generate a data access operation and comprising an error control block comprising a first ECC block implementing a first error control scheme and a second ECC block implementing a second error control scheme, and a flash memory device comprising a data storage block comprising a first data storage region including first flash memory cells and a second data storage region including second flash memory cells, wherein the first and second flash memory cells store a different number of data bits per memory cell, and wherein if the data access operation is directed to data stored in the first data storage region, the memory controller selects operation of the first ECC block such that the error control block operates in accordance with the first error control scheme, but if the data access operation is directed to data stored in the second data storage region, the memory controller selects operation of the second ECC block such that the error control block operates in accordance with the second error control scheme.

In yet another embodiment, the invention provides a method of controlling errors in a hybrid flash memory device including a first data storage region implemented with first flash memory cells and a second data storage region implemented with second flash memory cells, wherein the first and second flash memory cells store a different number of data bits per memory cell, and the method comprising; determining whether a data access operation is directed to data stored in the first data storage region or data stored in the second data storage region, and upon determining that the data access operation is directed to data stored in the first data storage region, selecting operation of a first ECC block to perform a first error control scheme in relation to data associated with the data access operation, and upon determining that the data access operation is directed to data stored in the second data storage region, selecting operation of a second ECC block to perform a second error control scheme in relation to data associated with the data access operation.

### BRIEF DESCRIPTION OF THE FIGURES

FIG. 1 is a block diagram of a flash memory device according to one embodiment of the invention;

FIG. 2 is a block diagram of a memory system according to one embodiment of the invention;

FIG. 3 is a block diagram of a flash memory device according to another embodiment of the invention;

FIG. 4 is an error control block of FIG. 3;

FIG. 5 is a block diagram of a memory system according to another embodiment of the invention;

FIG. 6 is a block diagram of a memory system according to further another embodiment of the invention;

FIG. 7 is a block diagram of a flash memory device according to further another embodiment of the invention;

FIG. 8 is a block diagram of a flash memory device according to further another embodiment of the invention;

FIG. 9 is a block diagram of a memory system according to further another embodiment of the invention; and

FIG. 10 is a block diagram of a smart card.

### DESCRIPTION OF EMBODIMENTS

Embodiments of the invention will now be described with reference to the accompanying drawings. The invention may, however, be embodied in many different forms and should not be constructed as being limited to only the illustrated embodiments. Rather, these embodiments are presented as teaching examples.

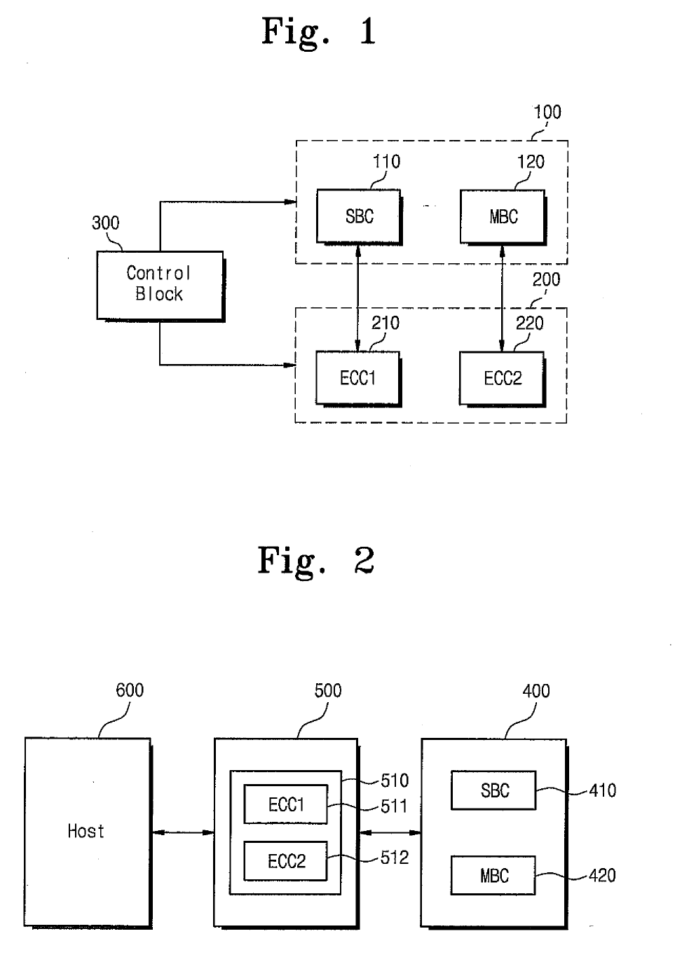

FIG. 1 is a block diagram of a flash memory device according to one embodiment of the invention.

Referring to FIG. 1, a flash memory device includes a data storage block 100, an error control block 200, and a control block 300. In this context the term “block” is used to generically denote a circuitry, firmware, or a combination of circuitry, control logic and related software capable of implementing a desired functionality.

Data storage block 100 includes a region 110 (hereinafter, referred to as a SBC region) including SBCs storing a single data bit per memory cell, and a region 120 (hereinafter, referred to as an MBC region) including MBCs storing multiple data bits per memory cell (i.e., “M-bit data” is stored, wherein M is an integer greater than 1). SBC region 110 may store amongst other data code information or ECC data. MBC region 120 will typically store bulk or payload data.

In certain embodiments of the invention, the flash memory cells provided in the SBC region 110 and MBC region 120 may be flash memory cells including a floating gate transistor. However, it will be apparent to those skilled in the art that the flash memory cells are not limited to only those including a floating gate transistor. For example, the flash memory cells may be implemented using charge trap transistors, etc. Furthermore, the flash memory cells may be PRAM, MRAM, or other types of non-volatile memory cells.

Referring to FIG. 1, error control block 200 generates error control code (ECC) with respect to data to be stored in data storage block 100. Error control block 200 may be used to detect and correct errors in data read from data storage block 100.

In this regard, error control block 200 includes a first ECC block 210 and a second ECC block 220. First ECC block 210 contains circuitry of conventional design capable of performing ECC operations in relation to the ECC data stored in SBC region 110. Second ECC block 220 contains circuitry of conventional design capable of performing ECC operations in relation to the payload data stored in MBC region 120.

That is, first ECC block 210 generates and manipulates ECC data related to data stored in SBC region 110 according to a first error control scheme. First ECC block 210 is thus capable of detecting and correcting errors in the data read from SBC region 110 according to the first error control scheme. Second ECC block 220 generates and manipulates ECC data related to data stored in MBC region 120 according to a second error control scheme. Second ECC block 220 is thus capable of detecting and correcting errors in data read from MBC region 120 according to the second error control scheme.

According to different embodiments of the invention, the first error control scheme may use a Bose, Ray-Chaudhuri, Hocquenghem (BCH) code or a Reed-Solomon (RS) code, such as that disclosed in U.S. Pat. No. 6,651,212. The second error control scheme may use a fractional read method sometimes referred to as soft decision (SD) method. This fractional read method is disclosed, for example, in U.S. Pat. No. 7,023,735, the subject matter of which is hereby incorporated as reference. However, it will be apparent to those skilled in the art that first and second error schemes may be otherwise implemented by existing and/or emerging ECC schemes, such as (e.g.,) those using repetition codes, parity codes, cyclic codes, hamming codes, golay codes, Reed-Muller codes, maximum likelihood, etc.

Control block 300 selects one of first ECC block 210 and second ECC block 220 according to whether a current data access operation is directed to data stored in SBC region 110 or MBC region 120. For example, if the data access operation requests data from SBC region 110, control block 300 selects first ECC block 210 and error control block 200 operates according to the first error control scheme. If a data access operation requested data from MBC region 120, control block 300 selects second ECC block 220 and error control block 200 operates according to the second error control scheme. An access operation request to data stored in either SBC region 110 or MBC region 120 may be determined in accordance with corresponding address information, command information, etc.

In this manner, optimized ECC performance may be obtained in relation to single-bit data or multi-bit data using different ECC schemes.

FIG. 2 is a block diagram of a memory system according to another embodiment of the invention.

Referring to FIG. 2, the memory system includes a flash memory device 400 and a memory controller 500. Flash memory device 400 includes a SBC region 410 and a MBC region 420. SBC region 410 and MBC region 420 respectively correspond to regions 110 and 120 of FIG. 1. It will be apparent to those skilled in the art that SBC region 410 and MBC region 420 may be embodied on a single integrated circuit chip.

Memory controller 500 controls data access (e.g., program and read) operations directed to flash memory device 400 according to commands received from host device 600. Memory controller 500 includes error control block 510 including a first ECC block 511 and a second ECC block 512. First ECC block 511 and second ECC block 512 respectively correspond to first ECC block 210 and the second ECC block 220 of FIG. 1. Memory controller 500 selects one of first ECC block 511 or second ECC block 512 in accordance with a data access operation indicated by a command received from host device 600 directed to data stored in SBC region 410 or MBC region 420.

For example, when a data access operation requests data stored in (or intended to be stored in) SBC region 410, memory controller 500 selects first ECC block 511, and error control block 510 operates according to the first error control scheme. If a data access operation requests data stored in (or intended to be stored in) MBC region 420, memory controller 500 selects second ECC block 512, and error control block 510 operates according to the second error control scheme.

In the embodiment illustrated in FIG. 2, flash memory device 400 and memory controller 500 may be implemented on a flash memory card. Alternately, memory controller 500 may be installed within a computer and flash memory device 400 may be separately provided. In the case where memory card 500 and flash memory device 400 are separately provided, memory controller 500 connected to flash memory device 400 using wireless, RF, magnetic, and/or direct electrical contact using any one of a number of standardized interfaces, such as ATA, SATA, USB, SCSI, ESDI, ISO, PCI, IDE, etc.

As before, optimized ECC performance may be obtained for single-bit data and multi-bit data by applying a selected error control scheme.

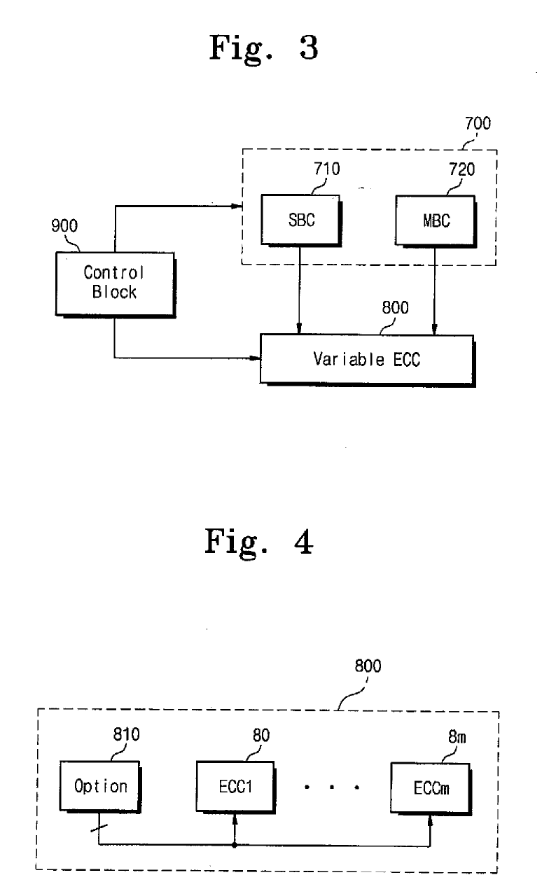

FIG. 3 is a block diagram of a flash memory device according to another embodiment of the present invention. FIG. 4 further illustrates the error control block 800 of FIG. 3.

The flash memory device generally illustrated in FIG. 3 comprises a data storage block 700, an error control block 800, and a control block 900. Data storage block 700 includes a SBC region 710 storing single-bit data and an MBC region 720 storing M-bit data as described above.

Referring to FIG. 3, however, error control block 800 variably generates ECC data with respect to the different types of data possibly stored in data storage block 700. Error control block 800 detects and corrects errors in data read from any portion of data storage block 700 using a corresponding error control scheme, such as one of those previously identified. In one embodiment, as illustrated in FIG. 4, error control block 800 comprises a plurality of error control schemes variously implemented in hardware and/or software and designed within error control block 800 as option block 810, and a plurality of ECC block 80 through 8m. That is, the respective ECC blocks 80 through 8m operate to respectively implement different error control schemes. For example, a first ECC block may be selected by means of option block 810 to be used in relation to data stored (or intended to be stored) in SBC region 710. Alternately, a second ECC block may be selected by means of option block 810 to be used in relation to data stored (or intended to be stored) in MBC region 720.

In certain embodiments of the invention, option block 810 may be implemented using conventional circuits and techniques such as fuse and bonding options. It will be apparent to those skilled in the art that option circuit 810 may be a programmable, or may be implemented in software. Error control block 800 according to embodiments of the invention may be used to selectively and variously implement a range of error control schemes.

Control block 900 of FIG. 3 may select one of first ECC block 80 or second ECC block 8m in accordance to whether the data being read or programmed is associated with SBC region 710 or MBC region 720, for example.

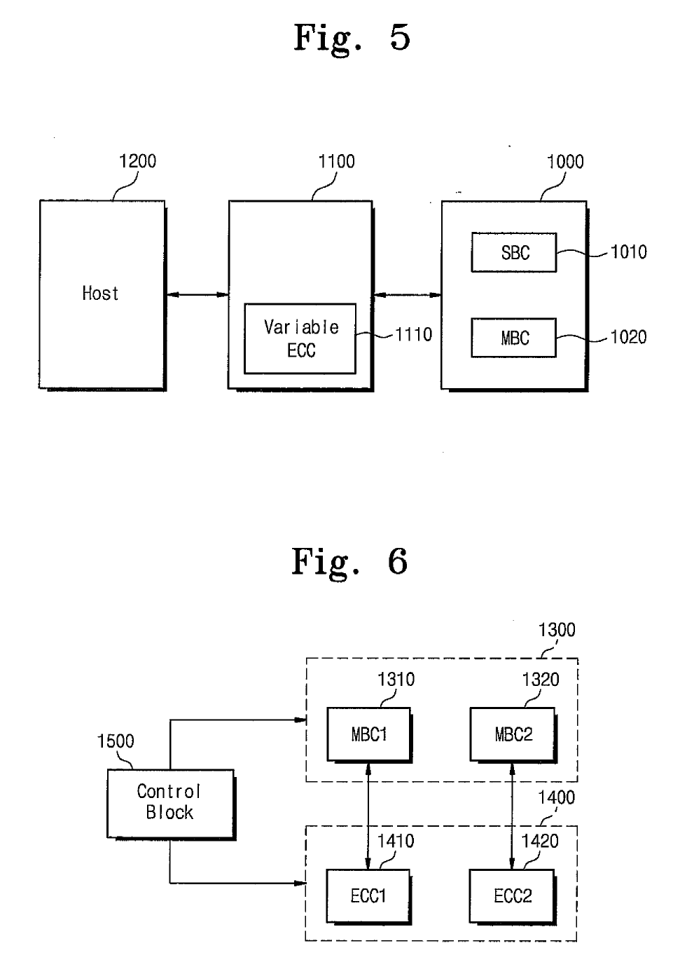

FIG. 5 is a block diagram of a memory system according to another embodiment of the invention.

Referring to FIG. 5, the memory system includes a flash memory device 1000 and a memory controller 1100. Flash memory device 1000 includes a SBC region 1010 and a MBC region 1020. SBC region 1010 and MBC region 1020 respectively correspond to regions 710 and 720 described in relation to FIG. 3. It will be apparent to those skilled in the art that SBC region 1010 and MBC region 1020 may be implemented on a single integrated circuit chip.

Memory controller 1100 controls data access operations directed to flash memory device 1000 in relation to a command received from host device 1200. Memory controller 1100 comprises an error control block 1110 which may be substantially identical to error control block 800 described in relation to FIG. 4. Thus, error control block 1110 contained in memory controller 1100 of FIG. 5 may include circuitry and software capable of implementing a number of different error control schemes.

For example, memory controller 1100 is able to select either a first ECC block or a second ECC block within error control block 1110 according to whether the data access operation indicated by host device 1200 is directed to data stored in (or intended to be stored in) SBC region 1010 or MBC region 1020.

In this particular embodiment, flash memory device 1000 and memory controller 1100 may be implemented on a flash memory card. Alternately, memory controller 1100 may be installed within a terminal device or computer, and the flash memory device separating provided. In the later case, memory controller 1100 may be connected to flash memory device 1000 via a standardized interface such as ATA, SATA, USB, SCSI, ESDI, ISO, PCI, and IDE using conventionally understood resources.

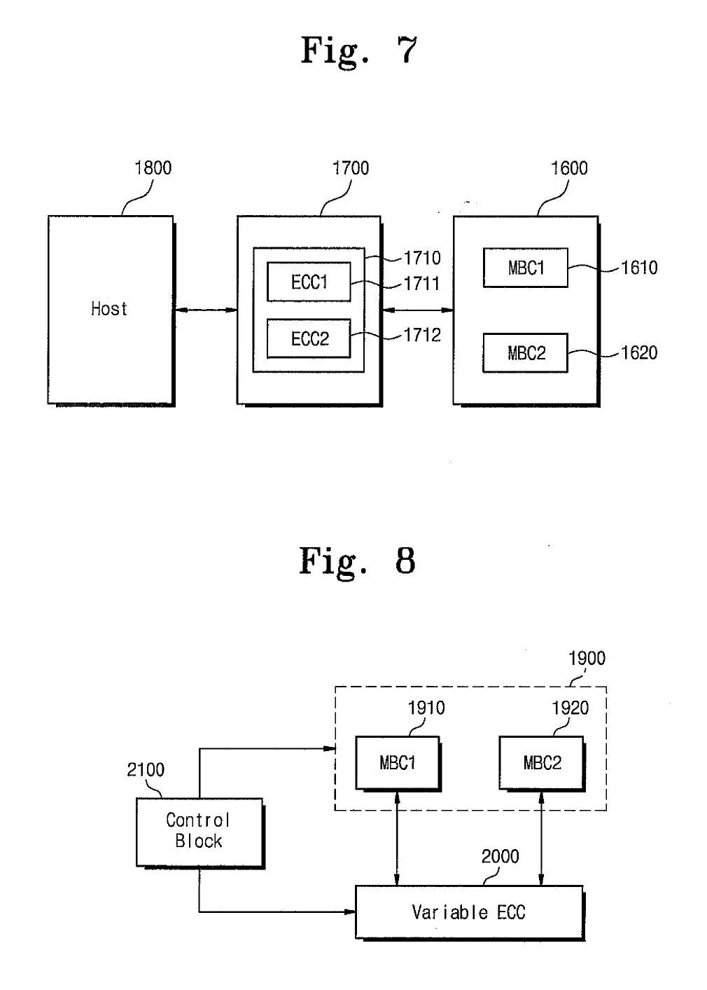

FIG. 6 is a block diagram of a memory system according to further another embodiment of the present invention.

Referring to FIG. 6, the memory system includes a data storage block 1300 comprising a first MBC region 1310 and a second MBC region 1320. First MBC region 1310 includes flash memory cells storing i-bit data, and second MBC region 1320 includes flash memory cells storing j-bit data, where i is a positive integer greater than j.

The memory system of FIG. 6 also comprises an error control block 1400 generating ECC data with respect to data stored (or intended to be stored) in data storage block 1300. Error control block 1400, including a first ECC block 1410 and a second ECC block 1420, may operate in relation to data storage block 1330, and more particularly in relation to first MBC region 1310 and a second MBC region 1320 within data storage block 1300 in a manner similar to that of error control block 200 in relation to data storage block 100 including first SBC region 110 and MBC region 120.

In the embodiment illustrated in FIG. 6, a first error control scheme implemented by first ECC block 1410 may use a BCG code or a RS code. The second error control scheme implemented by second ECC block 1410 may use a fractional read method. However, as before described, embodiments of the invention are not limited to only these error control schemes, but may make general use of other schemes such as repetition codes, parity codes, cyclic codes, hamming codes, golay codes, Reed-Muller codes, maximum likelihood, etc.

Control block 1500 may be used to select between first ECC block 1410 and second ECC block 1420 according to whether a data access operation is directed to data stored (or intended to be stored) in first MBC region 1310 or second MBC region 1320. For example, if a data access is directed to data stored in MBC region 1310, control block 1500 selects the operation of first ECC block 1410, and error control block 1400 operates according to the first error control scheme. However, if a data access is directed to data stored in second MBC region 1320, control block 1500 selects the operation of second ECC block 1420, and error control block 1400 operates according to the second error control scheme.

FIG. 7 is a block diagram of a flash memory system according to another embodiment of the invention. In this system illustrated in FIG. 7, data storage block 1600 is similar to data storage block 200 shown in FIG. 2, except that data storage block 1600 comprises first MBC1 region 1610 and second MBC2 1620, instead of SBC region 110 and a MBC region 120. The selection and provision of a competent error control scheme in relation to data respectively stored (or intended to be stored) in first MBC1 region 1610 or second MBC2 region 1620 may proceed similarly to the approach described in relation to FIG. 6.

FIG. 8 is a block diagram of a flash memory system according to another embodiment of the invention. The flash memory system of FIG. 8 is similar to that of FIG. 3 except that a data storage region includes first and second MBC regions MBC1 and MBC2. The selection and provision of a competent error control scheme in relation to data respectively stored (or intended to be stored) in first MBC1 region 1910 or second MBC2 region 1920 may proceed similarly to the approach described in relation to FIG. 6.

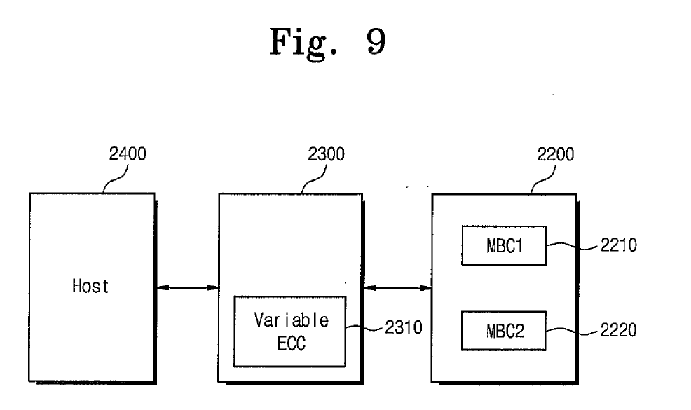

FIG. 9 is a block diagram of a flash memory system according to another embodiment of the invention. The flash memory system of FIG. 9 is similar to that of FIG. 5 except that a data storage region includes first and second MBC regions MBC1 and MBC2. The selection and provision of a competent error control scheme in relation to data respectively stored (or intended to be stored) in first MBC1 region 2210 or second MBC2 region 2220 may proceed similarly to the approach described in relation to FIG. 6.

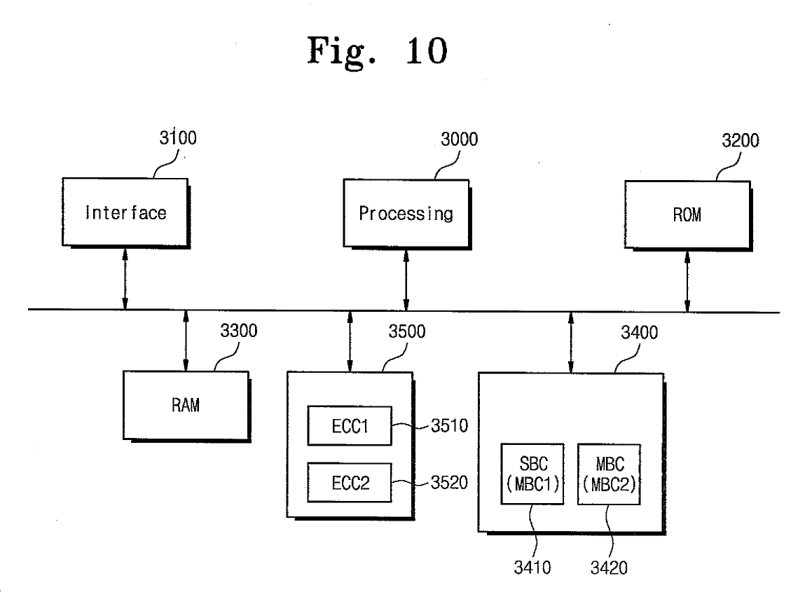

FIG. 10 is a general block diagram of a smart card into which any one of the foregoing embodiments may applied.

Referring to FIG. 10, the smart card comprises a processing unit 3000, an interface 3100, a ROM 3200, a RAM 3300, a flash memory device 3400, and an error control unit 3500. Although not being illustrated in the drawings, it is apparent to those skilled in the art that the smart card further includes an encoding/decoding block, a security block, etc. Flash memory device 3400 and the error control unit 3500 of FIG. 10 may be implemented according to any one of the embodiments previously described in relation FIGS. 1 through 9.

As described above, optimized ECC performance may be obtained by the use of different ECC schemes in relation to data stored in different portions of a flash memory device, e.g., as between a SBC memory array and a MBC memory array, or between different MBC arrays.

The above-disclosed subject matter is to be considered illustrative, and not restrictive, and the appended claims are intended to cover all such modifications, enhancements, and other embodiments, which fall within the scope of the invention. Thus, to the maximum extent allowed by law, the scope of the present invention is to be determined by the broadest permissible interpretation of the following claims and their equivalents, and shall not be restricted or limited to only the foregoing detailed description.

What is claimed is:

1. A hybrid flash memory device having an Error Control and Correction (ECC) capability, and comprising:
a control block responsive to an externally provided command;
a data storage block comprising a first data storage region including first flash memory cells and a second data storage region including second flash memory cells, wherein the first and second flash memory cells store a different number of data bits per memory cell; and
an error control block comprising a first ECC block implementing a first error control scheme and a second ECC block implementing a second error control scheme,
wherein if the command indicates a data access operation directed to data stored in the first data storage region, the control block selects operation of the first ECC block such that the error control block operates in accordance with the first error control scheme, and wherein if the command indicates a data access operation directed to data stored in the second data storage region, the control block selects operation of the second ECC block such that the error control block operates in accordance with the second error control scheme.

2. The device of claim 1, wherein each of the first flash memory cells stores 1-bit data, and each of the second flash memory cells stores M-bit data, wherein M is a positive integer greater than 1).

3. The device of claim 1, wherein each of the first flash memory cells stores i-bit data and each of the second flash memory cells stores j-bit data, where i is a positive integer greater than j.

4. The device of claim 3, wherein the i-bit data is 2-bit data and the j-bit data is 3-bit data, or the i-bit data is 3-bit data and the j-bit data is 4-bit data.

5. The device of claim 1, wherein the error control block comprises additional ECC blocks respectively implementing additional error control schemes, as selected by the control block.

6. The device of claim 1, wherein the first error control scheme uses at least one of a Bose, Ray-Chaudhuri, Hocquenghem (BCH) code and a Reed-Solomon (RS) code to control errors associated with data stored in the first flash memory cells.

7. The device of claim 1, wherein the second error control scheme implements at least one of a fractional read method and a maximum likelihood (ML) method to control errors associated with data stored in the second flash memory cells.

8. A memory system comprising:
a memory controller responsive to a command received from a host device to generate a data access operation and comprising an error control block comprising a first ECC block implementing a first error control scheme and a second ECC block implementing a second error control scheme; and
a flash memory device comprising a data storage block comprising a first data storage region including first flash memory cells and a second data storage region including second flash memory cells, wherein the first and second flash memory cells store a different number of data bits per memory cell,
wherein if the data access operation is directed to data stored in the first data storage region, the memory controller selects operation of the first ECC block such that the error control block operates in accordance with the first error control scheme, but if the data access operation is directed to data stored in the second data storage region, the memory controller selects operation of the second ECC block such that the error control block operates in accordance with the second error control scheme.

9. The memory system of claim 8, wherein each of the first flash memory cells stores 1-bit data, and each of the second flash memory cells stores M-bit data, wherein M is a positive integer greater than 1).

10. The memory system of claim 8, wherein each of the first flash memory cells stores i-bit data and each of the second flash memory cells stores j-bit data, where i is a positive integer greater than j.

11. The memory system of claim 10, wherein the i-bit data is 2-bit data and the j-bit data is 3-bit data, or the i-bit data is 3-bit data and the j-bit data is 4-bit data.

12. The memory system of claim 8, wherein the error control block comprises additional ECC blocks respectively implementing additional error control schemes as selected by the memory controller.

13. The memory system of claim 8, wherein the first error control scheme uses at least one of a Bose, Ray-Chaudhuri, Hocquenghem (BCH) code and a Reed-Solomon (RS) code to control errors associated with data stored in the first flash memory cells.

14. The memory system of claim 8, wherein the second error control scheme implements at least one of a fractional read method and a maximum likelihood (ML) method to control errors associated with data stored in the second flash memory cells.

15. The memory system of claim 8, wherein the flash memory device and the memory controller are commonly implemented on a flash memory card.

16. The memory system of claim 8, wherein the memory controller is implemented in a terminal device or a computer.

17. The memory system of claim 16, wherein the flash memory device is separately implemented from the memory controller and is capable of interfacing with the memory controller via an interface.

18. A method of controlling errors in a hybrid flash memory device including a first data storage region implemented with first flash memory cells and a second data storage region implemented with second flash memory cells, wherein the first and second flash memory cells store a different number of data bits per memory cell, and the method comprising:
determining whether a data access operation is directed to data stored in the first data storage region or data stored in the second data storage region; and
upon determining that the data access operation is directed to data stored in the first data storage region, selecting operation of a first ECC block to perform a first error control scheme in relation to data associated with the data access operation, and upon determining that the data access operation is directed to data stored in the second data storage region, selecting operation of a second ECC block to perform a second error control scheme in relation to data associated with the data access operation.

19. The method of claim 18, wherein each of the first flash memory cells stores 1-bit data, and each of the second flash memory cells stores M-bit data, wherein M is a positive integer greater than 1).

20. The method of claim 18, wherein each of the first flash memory cells stores i-bit data and each of the second flash memory cells stores j-bit data, where i is a positive integer greater than j.

21. The method of claim 20, wherein the i-bit data is 2-bit data and the j-bit data is 3-bit data, or the i-bit data is 3-bit data and the j-bit data is 4-bit data.

22. The method of claim 18, wherein the error control block comprises additional ECC blocks respectively implementing additional error control schemes, as selected by the control block.

23. The method of claim 18, wherein the first error control scheme uses at least one of a Bose, Ray-Chaudhuri, Hocquenghem (BCH) code and a Reed-Solomon (RS) code to control errors associated with data stored in the first flash memory cells.

24. The method of claim 18, wherein the second error control scheme implements at least one of a fractional read method and a maximum likelihood (ML) method to control errors associated with data stored in the second flash memory cells.
